(19) United States
(12) Patent Application Publication
(10) Pub. No.: US 2025/0004750 A1
(43) Pub. Date: Jan. 2, 2025

(54) CORRECTION METHOD AND DEVICE FOR ENERGY STORAGE BATTERY MANAGEMENT SYSTEM, AND SYSTEM AND MEDIUM

(71) Applicant: TRINA STORAGE SOLUTIONS (JIANGSU) CO., LTD., Changzhou, Jiangsu (CN)

(72) Inventor: Kai XU, Changzhou, Jiangsu (CN)

(73) Assignee: TRINA STORAGE SOLUTIONS (JIANGSU) CO., LTD., Changzhou, Jiangsu (CN)

(21) Appl. No.: 18/710,427

(22) PCT Filed: Nov. 14, 2022
(86) PCT No.: PCT/CN2022/131639

§ 371 Date: May 15, 2024

(30) Foreign Application Priority Data
Nov. 17, 2021 (CN) 202111362451.6

(51) Int. Cl. G06F 8/65; G06N 20/00

(52) U.S. Cl. CPC G06F 8/65; G06N 20/00

(57) ABSTRACT

Embodiments of the present disclosure provide a correction method for an energy storage battery management system, comprising: generating (S210) predictive data based on historical battery data by means of a twin model; training generic battery models according to the predictive data when a model correction event is detected, to obtain (S220) a target battery model; and issuing (S230) model update firmware or model update parameters of the target battery model to a local energy storage battery manager. The present disclosure further provides a correction device for an energy storage battery management system, and a system and a medium.

### TECHNICAL FIELD

The present disclosure relates to a correction method, device for an energy storage battery management system, and a system and a medium.

### BACKGROUND OF THE INVENTION

The widespread electrochemical energy storage applications have resulted in various operating conditions of battery cells. Also, it is difficult to ensure the consistency of electrochemical characteristics of battery cells from different manufacturers and production processes. In addition, affected by factors such as the uneven technical levels of integration vendors developing applications based on battery cells, the current application of electrochemical energy storage has the following issues: inconsistent cell balancing, inaccurate estimation of energy storage system SOC (State of Charge, battery state of charge), severe attenuation of battery health SOH (State of Health, battery health status), frequent occurrence of electrochemical energy storage system safety accidents, short time span of entire life cycle of electrochemical energy storage applications, and etc.

### SUMMARY OF THE INVENTION

Embodiments of the present disclosure provide a correction method, device for an energy storage battery management system, and a system and a medium.

At least one embodiment of the present disclosure provides a correction method for an energy storage battery management system, wherein the method is executed by a server, synchronously deployed on the server is a twin model of a battery model in a local energy storage battery manager and a plurality of generic battery models, the method comprising:
generating predictive data based on historical battery data by means of the twin model, wherein the historical battery data is battery data generated during the operation of an energy storage battery cluster;
training the generic battery models according to the predictive data when a model correction event is detected, to obtain a target battery model; and
issuing model update firmware or model update parameters of the target battery model to the local energy storage battery manager.

At least one embodiment of the present disclosure further provides a correction method for an energy storage battery management system, wherein the method is executed by a local energy storage battery manager, a battery model in the local energy storage battery manager is synchronously deployed on a server to run a twin model of the battery model on the server, the method comprises:
acquiring battery data generated by an energy storage battery cluster during operation, and reporting the battery data to the server at preset time intervals;
receiving model update firmware or model update parameters issued by the server, and verifying the model update firmware or model update parameters; and
upgrading model firmware or updating model parameters based on the model update firmware or model update parameters when the verification passes, to obtain a new battery model, and using the new battery model to manage the operating status of the energy storage battery cluster.

At least one embodiment of the present disclosure further provides a correction device for an energy storage battery management system, wherein the correction device is deployed in a server, synchronously deployed on the server is a twin model of a battery model in a local energy storage battery manager and a plurality of generic battery models, the correction device comprising:
a data prediction module configured to generate predictive data based on historical battery data by means of the twin model, wherein the historical battery data is battery data generated during the operation of an energy storage battery cluster;
a model training module configured to train the generic battery models according to the predictive data when a model correction event is detected, to obtain a target battery model; and
a model issuing module configured to issue model update firmware or model update parameters of the target battery model to the local energy storage battery manager.

At least one embodiment of the present disclosure further provides a correction device for an energy storage battery management system, wherein the correction device is configured in a local energy storage battery manager, a battery model in the local energy storage battery manager is synchronously deployed on a server to run a twin model of the battery model on the server, the correction device comprising:
a data reporting module configured to acquire battery data generated by an energy storage battery cluster during operation, and to report the battery data to the server at preset time intervals;
a model verification module configured to receive model update firmware or model update parameters issued by the server, and to verify the model update firmware or model update parameters; and
a model update module configured to upgrade model firmware or update model parameters based on the model update firmware or model update parameters to obtain a new battery model when the verification passes, and to use the new battery model to manage the operating status of the energy storage battery cluster.

At least one embodiment of the present disclosure further provides a correction system for an energy storage battery management system, comprising: at least two servers, a plurality of local energy storage battery managers and a plurality of energy storage battery clusters;
the at least two servers comprise a main server and the remaining number of backup servers, the main server and the backup servers run synchronously, the backup servers are configured to back up the data of the main server and are used instead of the main server to perform information interaction with the local energy storage battery managers when the main server is down;
the main server is communicatively connected with the plurality of local energy storage battery managers, and is configured to execute the correction method of the energy storage battery management system;
the local energy storage battery managers are communicatively connected to the plurality of energy storage battery clusters, respectively, and are configured to perform the correction method of the energy storage battery management system;
the energy storage battery clusters are configured to record battery data generated during operation and to send the battery data to the corresponding local energy storage battery manager.

At least one embodiment of the present disclosure further provides a storage medium containing computer-executable instructions, wherein the computer-executable instructions, when executed by a computer processor, are configured to perform the operations in the correction method for the energy storage battery management system as claimed above.

### BRIEF DESCRIPTION OF THE DRAWINGS

The following drawings are only intended to schematically illustrate and explain the present disclosure and do not limit the scope of the present disclosure, wherein:

FIG. 1 is a system structure diagram of a correction system of an energy storage battery management system provided by an embodiment of the present disclosure;

FIG. 2 is a flow chart of a correction method for an energy storage battery management system provided by another embodiment of the present disclosure;

FIG. 3 is a flow chart of a correction method for an energy storage battery management system provided by another embodiment of the present disclosure;

FIG. 4 is a flow chart of a correction method for an energy storage battery management system provided by another embodiment of the present disclosure;

FIG. 5 is a flow chart of a correction method for an energy storage battery management system provided by another embodiment of the present disclosure;

FIG. 6 is a flow chart of a correction method for an energy storage battery management system according to another embodiment of the present disclosure;

FIG. 7 is a structural block diagram of a correction device for an energy storage battery management system provided by an embodiment of the present disclosure;

FIG. 8 is a structural block diagram of a correction device for an energy storage battery management system provided by another embodiment of the present disclosure.

### DETAILED DESCRIPTION OF THE INVENTION

The present disclosure will be further described in detail below by means of the drawings and embodiments. Through these descriptions, the features and advantages of the present disclosure will become more apparent.

The wording “exemplary” is used exclusively herein to mean “serving as an example, embodiment, or illustration.” Any embodiment described herein as “exemplary” is not to be necessarily construed as preferred or advantageous over other embodiments. Although various aspects of the embodiments are shown in the drawings, the drawings are not necessarily drawn to scale unless otherwise noted.

Also, the technical features involved in different embodiments of the present disclosure described below can be combined as long as they do not conflict with each other.

It should also be noted that, for the convenience of description, the drawings only show parts related to the present disclosure rather than all structures.

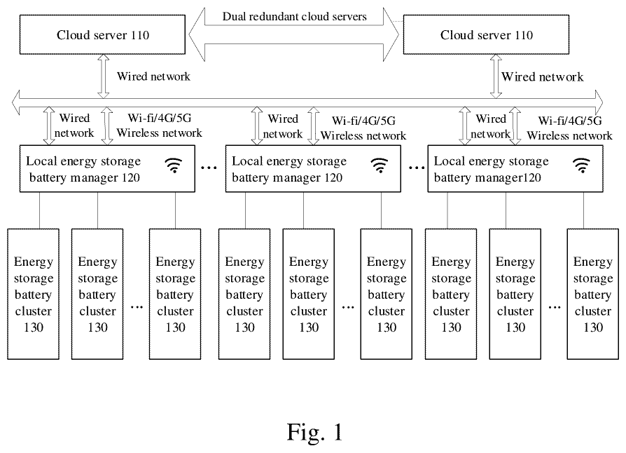

FIG. 1 is a system structure diagram of a correction system of an energy storage battery management system provided by an embodiment of the present disclosure. As shown in FIG. 1, the system includes at least two servers 110, a plurality of local energy storage battery managers 120 and a plurality of energy storage battery clusters 130.

The at least two servers 110 include a main server 110 and a remaining number of backup servers 110. The main server 110 and the backup servers 110 run in synchronisation. The backup servers 110 are configured to back up the data of the main server 110, and to perform information interaction with the local energy storage battery manager 120 instead of the main server 110 when the main server 110 is down.

The main server 110 is communicatively connected with the plurality of local energy storage battery managers 120, and is configured to perform the correction method of the energy storage battery management system as described in any embodiment of the present disclosure.

The local energy storage battery manager 120 is communicatively connected with the plurality of energy storage battery clusters 130, respectively, and is configured to perform the correction method of the energy storage battery management system as described in any embodiment of the present disclosure.

The energy storage battery cluster 130 is configured to record battery data generated during operation, and to send the battery data to the corresponding local energy storage battery manager 120.

The correction system for the energy storage battery management system further comprises a communication interaction device. The local energy storage battery manager 120 and the server 110 build a stable and fast communication link by means of the communication interaction device for two-way communication and interaction. Here, the communication interaction device comprises switches, routers, intelligent communication gateways, etc.

As shown in FIG. 1, a plurality of local energy storage battery managers 120 are located in the middle layer, respectively, each one of them corresponding to a plurality of energy storage battery clusters 130, and local energy storage battery manager 120 performs information interaction with the plurality of energy storage battery clusters 130 via a CAN communication link. Local energy storage battery manager 120 has a wired Ethernet interface and a wireless network interface. Local energy storage battery manager 120 builds a dual redundant communication link of wired network and wireless network links through the wired Ethernet interface, the wireless network interface, switches, intelligent communication gateways and wireless communication modules. Two-way information interaction is performed between local energy storage battery manager 120 and server 110 via the dual redundant communication link. Here, the wireless network link comprises Wi-Fi, 4G and 5G, etc.

In an embodiment of the present disclosure, both the server and the local energy storage battery manager are equipped with a real-time clock, and perform timing synchronisation processing during the procedure of system going online and normal daily interactions. The server and the local energy storage battery manager record current interaction events in real time according to their own conditions. For example, the interactive action events comprise: the event of cloud and local synchronising model, the event of machine learning prediction model training, the event of server generating determining prediction battery model, the event of cloud issuing upgrade local battery model, the event of cloud issuing upgrade local model parameters, the event of local receiving cloud upgrade model firmware, the event of local receiving cloud upgrade local battery model parameters, the event of local battery model upgrade success or failure, the event of local adjusting of model parameters success or failure, the event of cloud issued model upgrade firmware success/failure, the event of cloud issued adjusting of model parameters success/failure, the event of local received model upgrade firmware success/failure, the event of local received adjusting of model parameters success/failure, the event of local starting new model running, etc.

In an embodiment of the present disclosure, a plurality of local energy storage battery managers 120 and the corresponding multiple energy storage battery clusters 130 are deployed in an energy storage container. The server can be a single server host or a distributed server cluster.

In an embodiment of the present disclosure, two sets of primary and secondary servers 110 are deployed in the cloud, where the primary and secondary servers run synchronously. When one of the servers goes down, the other server is notified to immediately establish two-way information interaction with the local energy storage battery manager 120 to prevent the loss of communication interaction data and to ensure the safety and reliability of data transmission.

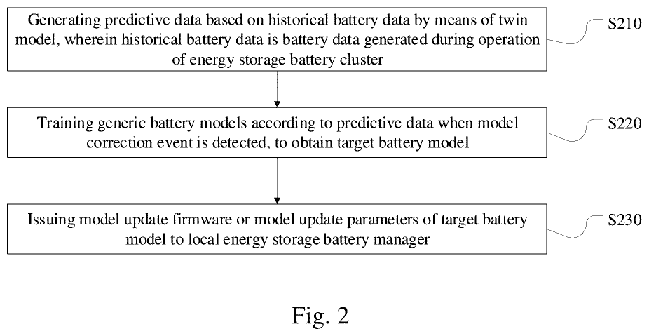

FIG. 2 is a flow chart of a correction method for an energy storage battery management system provided by another embodiment of the present disclosure. The embodiment may be applied to a scenario where a battery model is used to manage the operating status of an energy storage battery. The method may be performed by a correction device for the battery management system, which may be implemented by software and/or hardware, and is usually configured in a server, synchronously deployed on the server is a twin model of the battery model in the local energy storage battery manager and multiple generic battery models, the method comprising:

S210 Generating predictive data based on historical battery data by means of the twin model, wherein the historical battery data is battery data generated during operation of an energy storage battery cluster.

The twin model is a virtual entity that runs on the server side and is built in the same way as the battery model in the local battery manager and initialized with the same data. In the embodiment of the present disclosure, the method for synchronously deploying the twin model of the battery model in the local energy storage battery manager on the server may be: the local energy storage battery manager constructs an initial battery model generation code by means of a desktop simulation software, and then uses a hardware in the loop (HIL) device to simulate cell parameters, and trains the initial battery model with the cell parameters simulated by the hardware-in-the-loop HIL device to obtain an initialised battery model; the generated initialised battery model and code are synchronously arranged on the server and the local energy storage battery manager; at the same time, configure the corresponding model parameters to the local energy storage battery manager and the server to synchronize the model and model parameters; after synchronization, the system can be powered on to run, thereby ensuring that the battery model in the local energy storage battery manager and the twin model in the server are consistent during initialisation, thus improving the effectiveness of subsequent battery model updates.

The multiple generic battery models are battery models of batteries built based on different principles under ideal conditions. The battery models may comprise: internal resistance equivalent model Rint, Theveini equivalent circuit model, second-order RC equivalent circuit model, PNGV equivalent circuit model, GNL equivalent circuit model and improved hybrid circuit models, etc.

The historical battery data is the battery data of long-term running of the energy storage battery cluster reported to the server by the local energy storage battery manager. An energy storage battery management system (Battery Management System, hereinafter referred to as BMS) is deployed in the local energy storage battery manager. The BMS runs for a long time according to the built-in battery module and model default parameters. During the long-term operation, the BMS records the battery data of the energy storage battery cluster, and reports the battery data to the cloud server via a dual redundant communication link. The computing server stores the battery data during long-term operation as historical battery data. The BMS reports battery data to the cloud server at different collection intervals. The cloud server classifies the battery data during long-term operation according to different data types, and uses different storage cycles for various types of battery data to store historical data.

The predictive data is a possible working status data of the energy storage battery cluster in a future period predicted by the server based on historical battery data using a prediction algorithm. The prediction algorithm may comprise linear regression algorithms, logistic regression algorithms, support vector machine algorithms, random forest algorithms, etc.

After acquiring the data generated during the operation of the energy storage battery cluster uploaded by the local energy storage battery manager, the server separates the battery data according to different data types and stores historical battery data according to different storage cycles, and uses the originally deployed twin model corresponding to the battery model in the local energy storage battery manager to predict the operating status of the battery cluster in the future, thus obtaining predictive data. In the embodiment of the present disclosure, the twin model is used to predict the operating data of the energy storage battery cluster in the second time period as predictive data based on the historical battery data in the first time period. Here, the first time period and the second time period are both time periods set according to actual application scenarios. For example, the first time period can be a week, and the second time period can be a day. That is, the operating data of tomorrow may be predicted based on the historical battery data of the past week by means of the twin model. It can be understood that the first time period and the second time period may be configured by the user, or may be system default values.

S220 Training the generic battery models according to the predictive data when a model correction event is detected, to obtain a target battery model.

Model correction events are events that trigger the server to perform model optimisation iterations. The condition for triggering a model correction event may be that when it is determined that the local battery model needs to be optimized, a model correction event is triggered. When the local battery condition deviates greatly from the battery condition predicted by the server, a model correction event is triggered. By setting a battery operating condition deviation threshold, when the battery operating condition deviation is greater than the battery operating condition deviation threshold, it may be determined that the battery operating condition deviation meets the set conditions and a model correction event is triggered.

Exemplarily, a first operating curve is determined based on the predictive data. The battery data reported in real time by the local energy storage battery manager is acquired, and a second operating curve is determined based on the battery data in the second time period. The battery operating condition deviation is determined according to the second operating curve and the first operating curve. The first operating curve corresponding to the predictive data and the second operating curve corresponding to the battery data may be determined by means of curve fitting. The battery operating condition deviation is obtained by compare the deviation of the first operating curve and the second operating curve at the same time. For example, the deviation between the first operating curve and the second operating curve at the same time point (for example, the same hour or the same day, etc.) is compared as the battery operating condition deviation. When the battery operating condition deviation meets a set condition, a model correction event is triggered.

Machine learning algorithms may be algorithms known to the inventors which may be used to train a model, including least squares regression, robust regression, locally weighted least squares, SVM, logistic regression and multi-class classification, multi-feature optimal logistic regression, etc.

After predicting the operating status of the energy storage battery cluster in a future time period based on the historical battery data, when the real-time status reported by the battery does not match the predicted operating status, the server determines that a model correction event has been detected, and uses a machine learning algorithm to train multiple generic battery models already deployed in the server based on the predicted data to obtain multiple sub-models. A target sub-model used to update the local battery model is selected from the multiple sub-models according to the weight of the models, and a target battery module is formed by means of the target sub-model. It should be noted that the weight of the model may be determined by a degree of data difference between the predictive data of each sub-model and the predictive data determined by the twin model based on the same historical battery data. Here, the degree of data difference can be determined statistically. In the embodiment of the present disclosure, a fitting curve is obtained by fitting the predictive data, and the degree of data difference is determined by determining the deviation of the fitting curve. It can be understood that there are many ways to determine the data difference, which are not limited by the embodiments of the present disclosure. For example, the degree of data difference may be determined by calculating the mean, variance or standard deviation of each group of predicted data, respectively.

S230 Issuing model update firmware or model update parameters of the target battery model to the local energy storage battery manager.

Here, the model update firmware includes model code, the server sends the model code corresponding to the target battery model to the local energy storage battery manager via a reserved communication port, so that the local energy storage battery manager can perform firmware upgrade on the battery model.

Specifically, the server determines whether to update the battery model of the local energy storage battery manager or to adjust the model parameters of the local energy storage battery manager according to the comparison result of the battery operating condition deviation and a set threshold. When the battery operating condition deviation is greater than the set threshold, it is determined that a model update firmware of the target battery model is required to be issued to the local energy storage battery manager. The server determines the model update firmware corresponding to the target battery model, gives a command to update the local battery model, and issues the model update firmware corresponding to the target battery model to the local energy storage battery manager. When the battery operating condition deviation is less than or equal to the set threshold, it is determined that the model update parameters are required to be issued to the local energy storage battery manager. The server determines the model update parameters corresponding to the target battery model, gives a command to update the local battery model parameters, and issues the model update parameters corresponding to the target battery model to the local energy storage battery manager. The local battery model is iteratively updated by means of the model update firmware or model update parameters issued by the server.

The embodiment uses the twin model to generate the predictive data based on the historical battery data, where the historical battery data is battery data generated during the operation of the energy storage battery cluster; the generic battery models are trained according to the predictive data when a model correction event is detected, to obtain a target battery model; model update firmware or model update parameters of the target battery model are issued to the local energy storage battery manager to instruct the local energy storage battery manager to upgrade model firmware upgrade or update model parameters base on the model update firmware or model update parameters. That is, the battery model is optimised by means of the server, and the optimized battery model is synchronised to the local energy storage battery manager through firmware upgrade or parameter update, so as to use the optimised battery model to update the local battery model to ensure the effectiveness of the battery model in local energy storage battery management, thereby improving the balance consistency of the cells, improving the accurate assessment of the state of charge SOC of the energy storage system, and predicting the health of the energy storage battery SOH, energy storage system failure safety early warning, fault tracking, fault analysis, improving energy storage battery performance, and extending the battery life of the energy storage system throughout its life cycle.

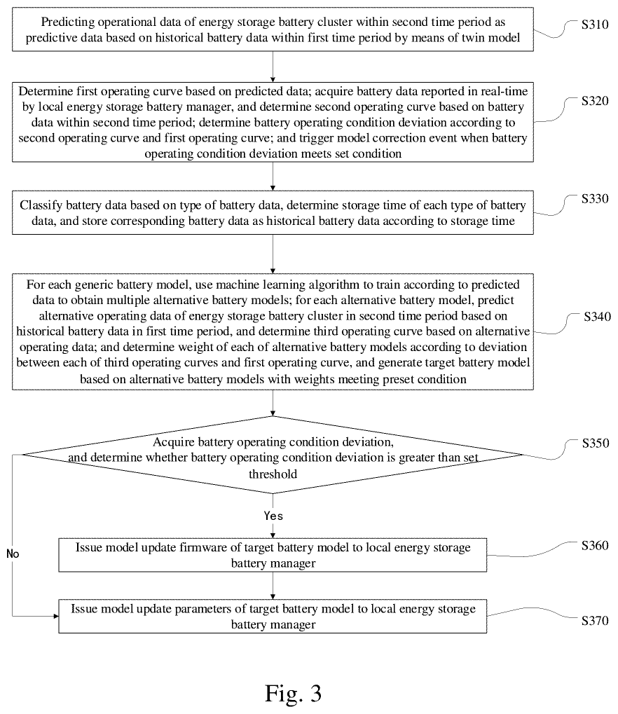

FIG. 3 is a flow chart of a correction method for an energy storage battery management system provided by another embodiment of the present disclosure. Based on the above embodiments, the embodiment further explains the correction method for the energy storage battery management system. Referring to FIG. 3, the method includes:

S310 Predicting operational data of the energy storage battery cluster within the second time period as the predictive data based on the historical battery data within the first time period by means of the twin model.

The first time period can be determined according to the time period corresponding to the data reported by the local energy storage battery manager. For example, if three days of battery data are reported, then the first time period is three days. The first time period can also be determined by the system according to the historical battery model correction frequency, so as to maximize the saving of computing resources on the basis of ensuring that the battery model is effective. It can also be determined according to a time period input by the operator, and the embodiment of the present disclosure does not impose too much limitation here.

The second time period represents the time length of the predictive data. For example, the predictive data for the next day can be predicted based on the historical battery data for the past three days.

In the embodiment of the present disclosure, the time length of the first time period is greater than the time length of the second time period. By acquiring more possible data to predict data in a shorter time, the accuracy of detection of triggering model correction event of the present disclosure is improved.

S320 Determining a first operating curve based on the predicted data; acquiring the battery data reported in real-time by the local energy storage battery manager, and determining a second operating curve based on the battery data within the second time period; determining a battery operating condition deviation according to the second operating curve and the first operating curve; and triggering a model correction event when the battery operating condition deviation meets a set condition.

After the first operating curve representing the predicted data and the second operating curve representing the actual data are obtained, the two may be displayed in an overlapped manner on a base reference frame to visually determine the difference between them. When the deviation between the two is greater than a preset threshold, it means that the battery model in the local energy storage battery manager cannot work effectively at this time and needs to be corrected, triggering a model correction event. When the deviation is less than the preset threshold, it means that the difference between the predicted data and the actual data is within the acceptable error range. Within the allowed error range, the model correction event will not be triggered.

S330 Classifying the battery data based on type of battery data, determining storage time of each type of battery data, and storing the corresponding battery data as the historical battery data according to the storage time.

In an exemplary embodiment, the battery data comprises: single cell temperature data, single cell voltage data, charge/discharge event data, charge capacity energy data, discharge capacity energy data, OCV-SOC data, internal resistance data, SOP data, cycle life data and self-discharge rate data.

The charge capacity energy data may include the charge capacity energy data at different temperatures and the charge capacity energy data at different rates. The discharge capacity energy data includes the discharge capacity energy data at different temperatures and the discharge capacity energy data at different rates. The OCV-SOC data includes discharge OCV-SOC data and charge OCV-SOC data. The internal resistance data includes the internal resistance data at different temperatures, the internal resistance data at different pulse currents, and the internal resistance data at different pulse durations. The SOP data includes the SOP data at different temperatures and the SOP data at different pulse durations.

For battery data, it can be divided into periodic data and non-periodic data. Periodic data refers to data that does not have long-term reference significance as the battery runs. For example, single cell temperature data is unstable and has too many influencing factors. When used as historical data, it has little reference significance for future forecast data, thus it is regarded as periodic data. Aperiodic data is related to the entire life cycle of the battery, with high reference significance, with stable data, and little influencing factors, such as cycle life data. For different types of battery data, the storage time is pre-configured. After receiving the battery data, the server classifies the battery data according to the type of battery data, and stores each battery data in a classified manner according to the pre-configured storage time for each type of battery data.

S340 For each generic battery model, using a machine learning algorithm to train according to the predicted data to obtain multiple alternative battery models; for each alternative battery model, predicting alternative operating data of the energy storage battery cluster in the second time period based on the historical battery data in the first time period, and determining a third operating curve based on the alternative operating data; and determining the weight of each of the alternative battery models according to a deviation between each of the third operating curves and the first operating curve, and generating a target battery model based on the alternative battery models with weights meeting a preset condition.

Since various types of generic battery models have been deployed in the server in advance, when it is determined that model correction is needed, a machine learning algorithm is used to train the above-mentioned generic battery models based on the historical battery data to obtain alternative battery models. For each candidate battery model, a prediction algorithm may be used to predict the battery operating data in the second time period as the alternative operating data based on the historical battery data in the first time period. Based on the alternative operating data, a linear fitting method is used to obtain a third operating curve corresponding to the alternative operating data of each alternative battery model, and the third curve is compared with the first operating curve corresponding to the predictive data predicted by the twin model based on the historical battery data in the same time period, thereby determining at least one optimal alternative battery models based on the comparison result, and generating a target battery model based on the optimal alternative battery models.

The embodiment of the present disclosure further comprises determining the weight of each alternative battery model. The weight may be determined by the size of deviation of the operating curve. For example, the weight of the alternative battery model is positively correlated to the deviation of the third operating curve and the first operating curve. That is, the greater the deviation between the two, the greater the weight of the alternative battery model; the smaller the deviation between the two, the smaller the weight of the alternative battery model. After determining the weight corresponding to each alternative battery model, the alternative battery model with a weight greater than the threshold is selected to form the target battery model.

S350 Acquiring a battery operating condition deviation, and determining whether the battery operating condition deviation is greater than a set threshold. If so, perform S360; otherwise, perform S370.

S360 Issuing model update firmware of the target battery model to the local energy storage battery manager.

S370 Issuing model update parameters of the target battery model to the local energy storage battery manager.

When the battery operating condition deviation is greater than the set threshold, the server determines that a large deviation has occurred in the operation of the battery model in the local energy storage battery manager, and the battery model of the local energy storage battery manager has to perform a firmware upgrade. When the battery operating condition deviation is less than or equal to the set threshold, the server determines that a small deviation has occurred in the operation of the battery model in the local energy storage battery manager, which can be overcome by correcting the parameters. The disclosed embodiment determines whether to perform a firmware upgrade on the local battery model based on the battery operating condition and the set threshold, can reasonably utilize the processing resources of the local energy storage battery manager to avoid occupying processing resources to process model firmware upgrades when firmware upgrades are not necessary.

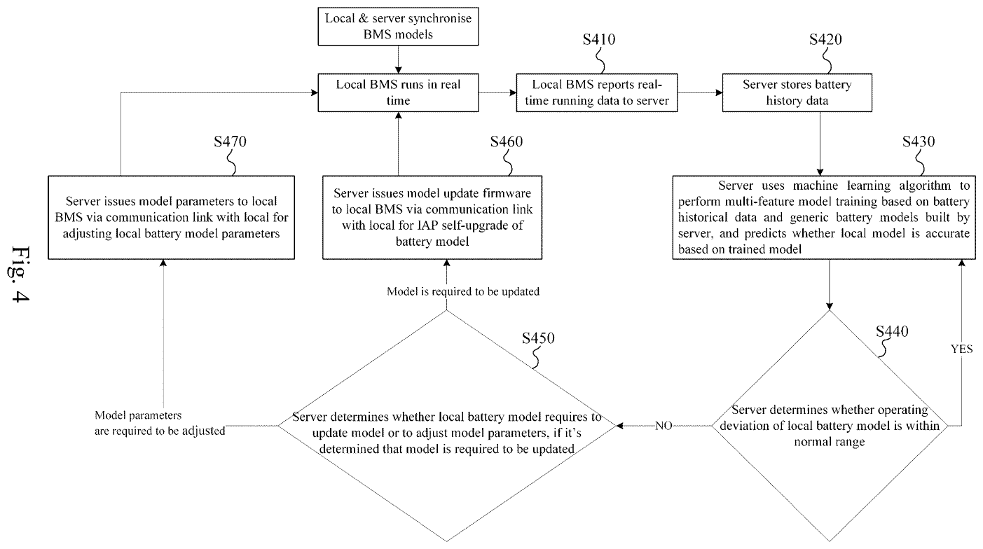

In an exemplary embodiment, the model optimisation steps on the server side are described in detail. FIG. 4 is a flow chart of a correction method for an energy storage battery management system provided by another embodiment of the present disclosure. As shown in FIG. 4, the method includes:

S410 The local BMS reports real-time running data to the server, and then performs S420.

S420 The server stores battery history data, and then performs S430.

S430 The server uses a machine learning algorithm to perform multi-feature model training based on the battery historical data and generic battery models built by the server, and predicts whether the local model is accurate based on the trained model.

S440 The server determines whether the operating deviation of the local battery model is within a normal range. If so, returns to perform 430 again. If not, S450 is subsequently performed.

S450 The server determines whether the local battery model requires to update model or to adjust model parameters, if it's determined that model is to be updated, then perform S460. If it is determined that the model parameters is to be adjusted, then S470 is performed.

S460 The server issues model update firmware to the local BMS via communication link with local for IAP self-upgrade of the battery model.

S470 The server issues model parameters to the local BMS via communication link with local for adjusting local battery model parameters.

It should be noted that after issuing model update parameters or model update firmware, the server is required to confirm whether the local energy storage battery manager has received the correct correction data, and whether the data can be processed properly to correct the local battery management system, and after the local energy storage battery manager model is upgraded or the model parameters are iteratively corrected, to start running of a new model or new model parameter operating mode adjustment.

The embodiment of the present disclosure deploys the twin model of the battery model in local energy storage battery management and multiple generic battery models on the server in advance, so that when problems arise based on the energy storage battery cluster operating data, on the basis of correcting the battery model in the local energy storage battery management by using the generic battery models, the historical data and the predicted data are further used to generate operating curves for comparison, which improves the accuracy and efficiency of triggering model correction time; from multiple alternative battery models, the best alternative battery model is selected based on the weights to form a target battery model, which enriches the selection range of the target battery model and ensures the effectiveness of the target battery model; it is determined to issue model update firmware or model update parameters based on the battery operating condition deviation, and make reasonable use of the processing resources of the local energy storage battery manager, thus improving the efficiency of model update.

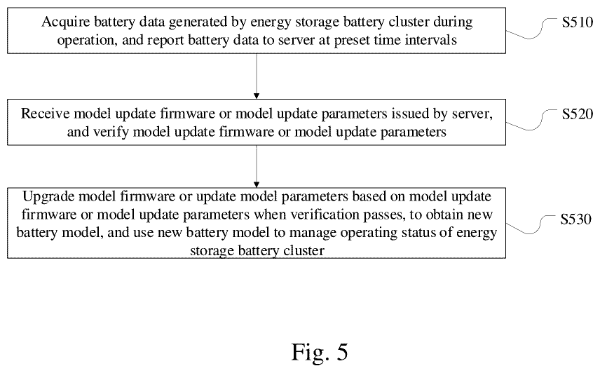

FIG. 5 is a flow chart of a correction method for an energy storage battery management system provided by another embodiment of the present disclosure. The embodiment may be applied to a scenario where a battery model is used to manage the operating status of an energy storage battery. The method may be performed by a correction device of an energy storage battery management system. The device may be implemented by software and/or hardware, and is usually configured in a local energy storage battery manager. The battery model in the local energy storage battery manager is synchronously deployed on the server to run a twin model of the battery model on the server, including:

S510 Acquiring battery data generated by the energy storage battery cluster during operation, and report the battery data to the server at preset time intervals.

The local energy storage battery manager may operate according to the actual operating conditions and the originally deployed battery default parameters. During long-term operation, the local energy storage battery manager may interact with multiple energy storage battery clusters via a preset communication interaction link to obtain battery data generated during the operation of the energy storage battery clusters, and report the obtained battery data to the server via the preset communication interaction link. Optionally, the battery data is reported to a server deployed with twin models and multiple generic battery models at different preset upload time intervals. Due to the difference in sampling accuracy, the local energy storage battery manager collects battery data at different time intervals, resulting in different upload time intervals for the battery data reporting server. For example, the local energy storage manager collects power pool data according to a preset accuracy and reports the battery data to the server according to the accuracy intervals.

In the embodiment of the present disclosure, the preset communication link may be a dual redundant communication link. For example, the wired network link of the dual redundant communication link is constructed by means of wired Ethernet interfaces, switches, routers, intelligent communication gateways and other devices. The wireless network link of the dual redundant communication link is constructed through wireless network interfaces, wireless modules, switches, routers, intelligent communication gateways and other devices. The server is configured in a primary and backup manner to build a stable dual communication loop and dual cloud server redundant communication link architecture.

S520 Receiving model update firmware or model update parameters issued by the server, and verifying the model update firmware or model update parameters.

Since the server delivers model update firmware or model update parameters to the local energy storage battery manager via the communication link, incorrect data in the model update firmware or model update parameters may occur due to network reasons. For example, during the transmission process, packets may be lost or maliciously tampered with. Therefore, in the embodiment of the present disclosure, the model update firmware or model update parameters issued by the server are verified to ensure that the dependency data of the local energy storage battery manager for the battery model update is correct.

In the embodiment of the present disclosure, if an error occurs in the verification, then the local energy storage battery manager feeds back the server and request a re-issuance of model update firmware or model update parameters to ensure that the local energy storage battery manager can complete the battery model update process.

S530 Upgrading model firmware or update model parameters based on the model update firmware or model update parameters when the verification passes, to obtain a new battery model, and using the new battery model to manage the operating status of the energy storage battery cluster.

In the embodiment of the present disclosure, after the model itself is updated by means of the verified model update firmware or model update parameters issued by the server, the local energy storage battery manager feeds back information of successful update to the server. After receiving the command to start running the new model issued by the server, the local battery energy storage manager starts the new battery model and manages the operating status of the energy storage battery cluster according to the updated battery model.

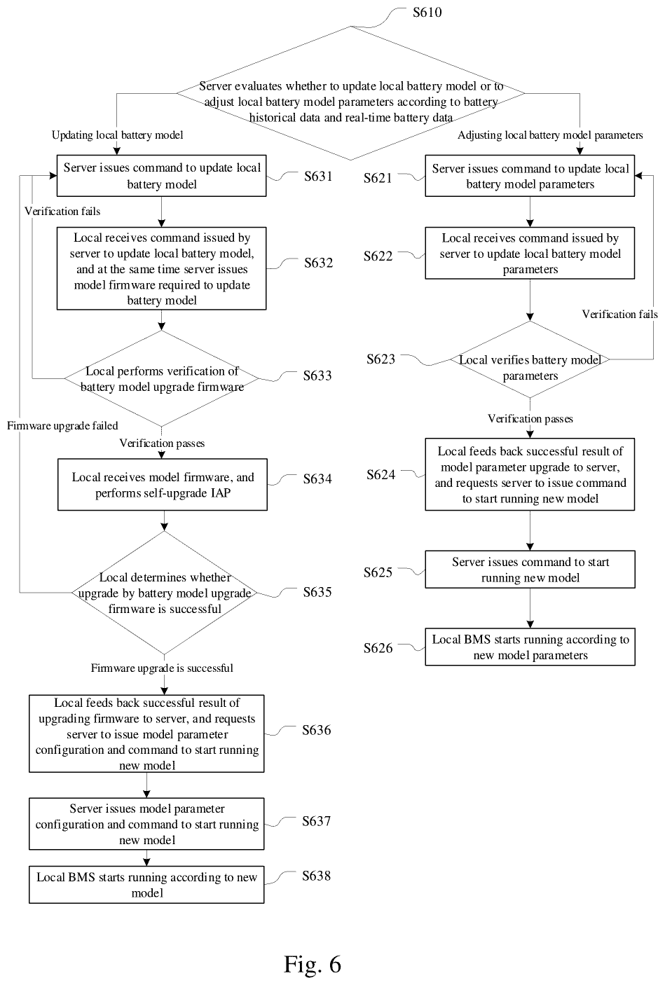

In an exemplary embodiment, the model iterative update steps on the local are described in detail. FIG. 6 is a flow chart of a correction method for an energy storage battery management system according to another embodiment of the present disclosure. As shown in FIG. 6, the method includes:

S610 The server evaluates whether to update local the battery model or to adjust the local battery model parameters according to the battery historical data and the real-time battery data. If the local battery model parameters are to be adjusted, then S621 is performed. If the local battery model is to be updated, then jump to and start performing S631.

S621 The server issues a command to update the local battery model parameters, and then performs S622.

S622 The local receives the command issued by the server to update the local battery model parameters, and subsequently performs S623.

S623 The local verifies the battery model parameters. If the verification passes, then S624 is subsequently performed. If the verification fails, return to S621 again.

S624 The local feeds back the successful result of model parameter upgrade to the server, and requests the server to issue a command to start running the new model, and then performs S625.

S625 The server issues the command to start running the new model, and then performs S626.

S626 The local BMS starts running according to the new model parameters.

S631 The server issues a command to update the local battery model, and then performs S632.

S632 The local receives the command issued by the server to update the local battery model, and at the same time, the server issues the model firmware required to update the battery model, and then performs S633.

S633 The local performs verification of battery model upgrade firmware. If the verification passes, S634 is subsequently performed. If the verification fails, return to S631 again.

S634 The local receives the model firmware, performs self-upgrade IAP, and subsequently performs S635.

S635 The local determines whether the upgrade by the battery model upgrade firmware is successful. If the firmware upgrade is successful, then S636 is subsequently performed. If the firmware upgrade fails, return to S631 again.

S636 The local feeds back the successful result of upgrading firmware to the server, and requests the server to issue the model parameter configuration and a command to start running the new model, and then performs S637.

S637 The server issues the model parameter configuration and the command to start running the new model, and then performs S638.

S638 The local BMS starts running according to the new model.

In the embodiment of the present disclosure, the local battery energy storage manager acquires the battery data generated by the energy storage battery cluster during operation, reports the battery data to the server at preset time intervals; receives the model update firmware or model update parameters issued by the server, verifies the model update firmware or model update parameters; performs model firmware upgrade or model parameter update on the battery model based on the model update firmware or model update parameters that pass the verification, to obtain a new battery model. The new battery model is used to manage the operating status of the energy storage battery cluster. That is, the local energy storage battery manager may achieve high-precision update and usage of the battery model by simple data upload and data reception processing, thus reducing the computing requirements for the local energy storage battery manager, on the basis of improving the balance consistency of the cells, improving the accurate assessment of the state of charge SOC of the energy storage system, predicting the health of the energy storage battery SOH, and providing early warning of energy storage system failure safety, fault tracking, fault analysis, improving energy storage battery performance, and extending the battery life of the energy storage system throughout its life cycle, further improves the applicability and compatibility of the disclosed correction method for different scenarios.

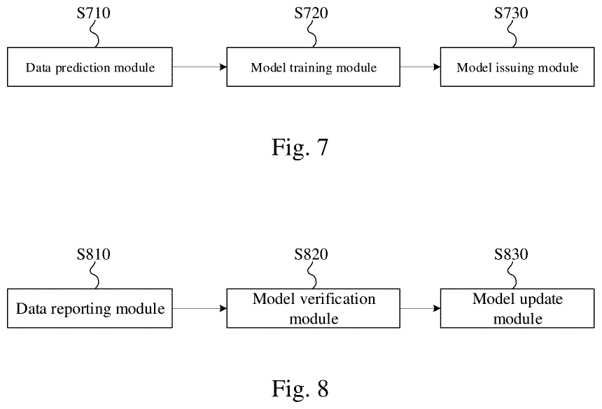

FIG. 7 is a structural block diagram of a correction device for an energy storage battery management system provided by an embodiment of the present disclosure. The device may be implemented by software and/or hardware, and is usually deployed in a server. Synchronously deployed on the server is a twin model of the battery model in the local energy storage battery manager and multiple generic battery models. The device may comprises:
A data prediction module 710 configured to generate predictive data based on historical battery data by means of the twin model, wherein the historical battery data is battery data generated during the operation of an energy storage battery cluster;
A model training module 720 configured to train the generic battery models according to the predictive data when a model correction event is detected, to obtain a target battery model;
A model issuing module 730 configured to issue model update firmware or model update parameters of the target battery model to the local energy storage battery manager.

The correction device for the energy storage battery management system provided by the embodiments of the present disclosure may perform the correction method of the energy storage battery management system provided by any embodiment of the present disclosure, and has functional modules and beneficial effects corresponding to the performance of the method.

The data prediction module 710 is configured to use the twin model to predict the operating data of the energy storage battery cluster in the second time period as predictive data based on the historical battery data in the first time period.

In an embodiment of the present disclosure, the device further includes:
An event triggering module configured to determine the first operating curve according to the predicted data after generating the predictive data based on the historical battery data by using the twin model; acquire the battery data reported in real time by the local energy storage battery manager, and determine a second operating curve according to the battery data in the second time period; determine a battery operating condition deviation based on the second operating curve and the first operating curve; trigger the model correction event when the battery operating condition deviation meets a set condition.

The correction device for the energy storage battery management system further comprises: a data storage module.

The data storage module is configured to classify the battery data based on the type of the battery data, determine the storage time of each type of battery data, and store the corresponding battery data as a historical battery data according to the storage time. The battery data includes at least one of single cell temperature data, single cell voltage data, charge/discharge event data, charging capacity energy data, discharge capacity energy data, OCV-SOC data, internal resistance data, SOP data, cycle life data and self-discharge rate data.

The model training module 720 is configured to, for each generic battery model, use a machine learning algorithm to train according to the predictive data to obtain multiple candidate battery models; for each candidate battery model, predict the alternative operating data of the energy storage battery cluster in the second time period based on the historical battery data in the first time period, and determine a third operating curve based on the alternative operating data; determine the weight of each of the candidate battery models according to the deviation of each of the third operating curves and the first operating curve, and generate a target battery model according to the candidate battery model with weight meeting a preset condition.

The model delivery module 730 is configured to issue the model update firmware of the target battery model to the local energy storage battery manager when the battery operating condition deviation is greater than a set threshold; and to issue the model update parameters of the target battery model to the local energy storage battery manager when the battery operating condition deviation is less than or equal to the set threshold.

After further explanation, the correction device for the energy storage battery management system provided by the embodiments of the present disclosure can also execute the correction method for the energy storage battery management system provided by any embodiment of the present disclosure, and has the corresponding functional modules and beneficial effects of the performance of the method.

FIG. 8 is a structural block diagram of a correction device for an energy storage battery management system provided by another embodiment of the present disclosure. The device may be implemented by software and/or hardware, and is usually configured in a local energy storage battery manager. The battery model in the local energy storage battery manager is synchronously deployed on the server to run the twin model of the battery model in the server. The device may include:
A data reporting module 810 configured to acquire battery data generated by the energy storage battery cluster during operation, and to report the battery data to the server at preset time intervals;
A model verification model 820 configured to receive the model update firmware or model update parameters issued by the server, and to verify the model update firmware or model update parameters;
A model update module 830 configured to perform model firmware upgrade or model parameter update on the battery model based on the model update firmware or model parameters that pass the verification, to obtain a new battery model, and use the new battery model to manage the operating status of the energy storage battery cluster.

The correction device for the energy storage battery management system provided by the embodiments of the present disclosure may execute the correction method for the energy storage battery management system provided by any embodiment of the present disclosure, and has functional modules and beneficial effects corresponding to the performance of the method.

The embodiment of the present disclosure further provides a storage medium comprising computer executable instructions, wherein the computer executable instructions, when executed by a computer processor, are configured to perform operations in a correction method for an energy storage battery management system.

The method can be executed by a server, synchronously deployed in the server is a twin model of the battery model in the local energy storage battery manager and multiple generic battery models, the method comprising: generating predictive data based on historical battery data by means of the twin model, wherein the historical battery data is battery data generated during the operation of the energy storage battery cluster; training the generic battery models according to the predictive data when a model correction event is detected, to obtain a target battery model; and issuing model update firmware or model update parameters of the target battery model to the local energy storage battery manager.

Alternatively, the method may be executed by a local energy storage battery manager, and the battery model in the local energy storage battery manager is synchronously deployed on the server, so as to run a twin model of the battery model in the server, the method including: acquiring battery data generated by the energy storage battery cluster during operation, reporting the battery data to the server at preset time intervals; receiving model update firmware or model update parameters issued by the server, verifying the model update firmware or model update parameters; and performing model firmware upgrade or model parameter update on the battery model based on the model update firmware or model update parameters when the verification passes, to obtain a new battery model, using the new battery model to manage the operating status of the energy storage battery cluster.

Of course, for the storage medium containing computer-executable instructions provided by the embodiments of the disclosure provide, the computer-executable instructions are not limited to the method operations described above, and can also execute the related operations in the correction method for the energy storage battery management system provided by any embodiment of the disclosure.

From the above description of the implementation, those skilled in the art can clearly understand that the present disclosure can be implemented with the help of software and necessary general hardware. Of course, it can also be implemented with hardware, but in many cases the former is a better implementation. Based on this understanding, the technical solution of the present disclosure can be embodied in the form of a software product in essence or that contributes to the prior art. The computer software product can be stored in a computer-readable storage medium, such as a computer floppy disk, read-only memory (Read-Only Memory, ROM), random access memory (Random Access Memory, RAM), flash memory (FLASH), hard disk or optical disk, etc., including a number of instructions to make a computer device (which can be a personal computer, server, or network device, etc.) to perform the methods described in various embodiments of the present disclosure.

It is worth noting that in the above embodiments of the correction device for the energy storage battery management system, the various units and modules included are only divided according to functional logic, but are not limited to the above divisions, as long as the corresponding functions can be realized; in addition, the specific names of each functional unit are only for the convenience of distinguishing each other and are not used to limit the scope of protection of the present disclosure.

Note that the above are only embodiments of the present disclosure and the technical principles used. Those skilled in the art will understand that the present disclosure is not limited to the specific embodiments described herein, and that various obvious changes, readjustments, and substitutions can be made by those skilled in the art without departing from the scope of the disclosure. Therefore, although the present disclosure has been described in detail through the above embodiments, the present disclosure is not limited to the above embodiments, and may also include more other equivalent embodiments without departing from the concept of the present disclosure, and the scope of the present disclosure is determined by the scope of the attached claims.

Although the present disclosure provides method operation steps as described in the embodiments or flow charts, more or fewer operation steps may be included based on conventional or non-inventive efforts. The sequence of steps listed in the embodiment is only one way of executing the sequence of many steps, and does not represent the only execution sequence. When the actual device or client product is executed, it may be executed sequentially or in parallel (for example, in a parallel processor or multi-threaded processing environment) according to the methods shown in the embodiments or figures.

Those skilled in the art will understand that embodiments of the present specification may be provided as methods, devices (systems) or computer program products. Accordingly, embodiments of the present description may take the form of an entirely hardware embodiment, an entirely software embodiment, or an embodiment that combines software and hardware aspects. Furthermore, the present disclosure may take the form of a computer program product embodied on one or more computer-usable storage media (including, but not limited to, disk storage, CD-ROM, optical storage, etc.) having computer-usable program code embodied therein.

The disclosure is described with reference to flowchart illustrations and/or block diagrams of methods, apparatus (systems) and computer program products according to embodiments of the disclosure. It will be understood that each process and/or block in the flowchart illustrations and/or block diagrams, and combinations of processes and/or blocks in the flowchart illustrations and/or block diagrams, can be implemented by computer program instructions. These computer program instructions may be provided to a processor of a general purpose computer, special purpose computer, embedded processor, or other programmable data processing device to produce a machine such that execution of the instructions by the processor of the computer or other programmable data processing device produces a device configured for implementing the functions specified in a process or processes of a flowchart and/or a block or blocks of a block diagram.

These computer program instructions may also be stored in a computer-readable memory that causes a computer or other programmable data processing apparatus to operate in a particular manner, such that the instructions stored in the computer-readable memory produce an article of manufacture including the instruction device, the instruction device implements the functions specified in a process or processes in the flowchart and/or in a block or blocks in the block diagram.

These computer program instructions may also be loaded onto a computer or other programmable data processing device, causing a series of operating steps to be performed on the computer or other programmable device to produce computer-implemented processing, so that the instructions executed on the computer or other programmable device provide steps configured to implement the functions specified in a process or processes of a flowchart diagram and/or a block or blocks of a block diagram.

Each embodiment in this specification is described in a progressive manner. The same and similar parts between the various embodiments can be referred to each other. Each embodiment focuses on its differences from other embodiments. In particular, for the system embodiment, since it is basically similar to the method embodiment, the description is relatively simple. For relevant details, please refer to the partial description of the method embodiment. In this document, relational terms such as first, second, etc. are used only to distinguish one entity or operation from another entity or operation and do not necessarily require or imply the existence of actual relationship or sequence among any such entity or operation.

It should be noted that, as long as there is no conflict, the embodiments and features in the embodiments of the present disclosure can be combined with each other. The present disclosure is not limited to any single aspect, nor to any single embodiment, nor to any combination and/or permutation of these aspects and/or embodiments. Furthermore, each aspect and/or embodiment of the disclosure may be used alone or in combination with one or more other aspects and/or embodiments thereof.

Finally, it should be noted that the above embodiments are only used to illustrate the technical solution of the present disclosure, but not to limit it; although the present disclosure has been described in detail with reference to the foregoing embodiments, those of ordinary skill in the art should understand that: The technical solutions described in the foregoing embodiments can still be modified, or some or all of the technical features can be equivalently replaced; and these modifications or substitutions do not deviate from the essence of the corresponding technical solutions from the technical solutions of the embodiments of the present disclosure, they should be covered by the claims and the scope of the description of this disclosure.

1. A correction method for an energy storage battery management system, wherein the method is executed by a server, synchronously deployed on the server are a twin model of a battery model in a local energy storage battery manager and a plurality of generic battery models, the method comprising:
generating predictive data based on historical battery data by means of the twin model, wherein the historical battery data is battery data generated during the operation of an energy storage battery cluster;
training the generic battery models according to the predictive data when a model correction event is detected, to obtain a target battery model; and
issuing model update firmware or model update parameters of the target battery model to the local energy storage battery manager.

2. The method according to claim 1, wherein generating the predictive data based on the historical battery data by means of the twin model comprises:
predicting an operational data of the energy storage battery cluster within a second time period as the predictive data based on the historical battery data within a first time period by means of the twin model.

3. The method according to claim 2, wherein the method further comprises, after generating the predictive data based on the historical battery data by means of the twin model:
determining a first operating curve based on the predicted data;
acquiring battery data reported in real-time by the local energy storage battery manager, and determining a second operating curve based on the battery data within the second time period;
determining a battery operating condition deviation according to the second operating curve and the first operating curve; and
triggering the model correction event when the battery operating condition deviation meets a set condition.

4. The method according to claim 3, wherein the method further comprises, after acquiring battery data reported in real time by the local energy storage battery manager:
classifying the battery data based on the type of the battery data, determining a storage time of each type of the battery data, and storing the corresponding battery data as the historical battery data according to the storage time.

5. The method according to claim 1, wherein the battery data comprises at least one of single cell temperature data, single cell voltage data, charge/discharge event data, charge capacity energy data, discharge capacity energy data, OCV-SOC data, internal resistance data, SOP data, cycle life data and self-discharge rate data.

6. The method according to claim 3, wherein training the generic battery model according to the predictive data to obtain a target battery model comprises:
for each generic battery model, using a machine learning algorithm to train according to the predicted data to obtain multiple alternative battery models;
for each alternative battery model, predicting alternative operating data of the energy storage battery cluster in the second time period based on the historical battery data in the first time period, and determining a third operating curve based on the alternative operating data; and
determining the weight of each of the alternative battery models according to a deviation between each of the third operating curves and the first operating curve, and generating a target battery model based on the alternative battery models with weights meeting a preset condition.

7. The method according to claim 3, wherein issuing model update firmware or model update parameters of the target battery model to the local energy storage battery manager comprises:
issuing model update firmware of the target battery model to the local energy storage battery manager when the battery operating condition deviation is greater than a set threshold; and
issuing the model update parameters of the target battery model to the local energy storage battery manager when the battery operating condition deviation is less than or equal to the set threshold.

8. A correction method for an energy storage battery management system, wherein the method is executed by a local energy storage battery manager, a battery model in the local energy storage battery manager is synchronously deployed on a server to run a twin model of the battery model on the server, the method comprises:
acquiring battery data generated by an energy storage battery cluster during operation, and reporting the battery data to the server at preset time intervals;
receiving model update firmware or model update parameters issued by the server, and verifying the model update firmware or model update parameters; and
upgrading model firmware or updating model parameters based on the model update firmware or model update parameters when the verification passes, to obtain a new battery model, and using the new battery model to manage the operating status of the energy storage battery cluster.

9-10. (canceled)

11. A correction system for an energy storage battery management system,
comprising: at least two servers, a plurality of local energy storage battery managers and a plurality of energy storage battery clusters;
the at least two servers comprise a main server and the remaining number of backup servers, the main server and the backup servers run synchronously, the backup servers are configured to back up the data of the main server and are used instead of the main server to perform information interaction with the local energy storage battery managers when the main server is down;
the main server is communicatively connected with the plurality of local energy storage battery managers, and is configured to execute a first correction method for an energy storage battery management system, wherein synchronously deployed on the main server are a twin model of a battery model in the local energy storage battery manager and a plurality of generic battery models, the first method comprising:
generating predictive data based on historical battery data by means of the twin model, wherein the historical battery data is battery data generated during the operation of an energy storage battery cluster;
training the generic battery models according to the predictive data when a model correction event is detected, to obtain a target battery model; and
issuing model update firmware or model update parameters of the target battery model to the local energy storage battery manager;
the local energy storage battery managers are communicatively connected to the plurality of energy storage battery clusters, respectively, and are configured to perform a second correction method for an energy storage battery management system, wherein a battery model in the local energy storage battery manager is synchronously deployed on the main server to run the twin model of the battery model on the main server, the second method comprising:
acquiring battery data generated by the energy storage battery cluster during operation, and reporting the battery data to the main server at preset time intervals;
receiving model update firmware or model update parameters issued by the main server, and verifying the model update firmware or model update parameters; and
upgrading model firmware or updating model parameters based on the model update firmware or model update parameters when the verification passes, to obtain a new battery model, and using the new battery model to manage the operating status of the energy storage battery cluster;
the energy storage battery clusters are configured to record battery data generated during operation and to send the battery data to the corresponding local energy storage battery manager.

12. A storage medium containing computer-executable instructions, wherein the computer-executable instructions, when executed by a computer processor, are configured to perform the operations in the correction method for the energy storage battery management system of claim 1.

13. A storage medium containing computer-executable instructions, wherein the computer-executable instructions, when executed by a computer processor, are configured to perform the operations in the correction method for the energy storage battery management system of claim 8.
